(19) United States
(12) Patent Application Publication
(10) Pub. No.: US 2026/0277356 A1
(43) Pub. Date: Sep. 17, 2026

(54) DISPLAY DEVICE INCLUDING A NOISE SHIELDING LAYER AND ELECTRONIC DEVICE USING THE SAME

(71) Applicant: SAMSUNG DISPLAY CO., LTD., YONGIN-SI (KR)

(72) Inventor: Sung Ku KANG, Yongin-si (KR)

(21) Appl. No.: 19/426,801

(22) Filed: Dec. 19, 2025

(30) Foreign Application Priority Data
Mar. 13, 2025 (KR) 10-2025-0032539

(51) Int. Cl. G06F 3/041; G09G 3/32

(52) U.S. Cl. CPC G06F 3/0416; G06F 3/0412; G09G 3/32; G06F 2203/04107; G09G 2300/0426

(57) ABSTRACT

The present disclosure relates to a display device and an electronic device using the same. According to an embodiment of the disclosure, a display device comprising a display panel displaying an image; and a display driving circuit controlling an image display operation of pixels formed in the display panel, wherein the display panel includes a display module including a thin film transistor layer, a light emitting element layer, and an encapsulation layer on a substrate, a noise shielding layer formed on a front surface of the display module in a planar mesh type, and a touch sensing unit arranged in front of the noise shielding layer.

### CROSS-REFERENCE TO RELATED APPLICATION

The present application claims priority under 35 U.S.C. §119 to Korean Patent Application No. 10-2025-0032539, filed on Mar. 13, 2025 in the Korean Intellectual Property Office, the contents of which are herein incorporated by reference in their entirety.

### TECHNICAL FIELD

The present disclosure relates to a display device and, more specifically, to a display device including a noise shielding layer and an electronic device using the same.

### DISCUSSION OF THE RELATED ART

With the advancement of the information age, the demand for a display device for displaying an image in various forms has increased. For example, the display device has been applied to various electronic devices such as a smart phone, a digital camera, a laptop/notebook computer, a navigation device and a smart television.

The display device may be a flat panel display device such as a liquid crystal display (LCD) device, a field emission display device and an organic light emitting diose (OLED) display device. The light emitting diode display device of the flat panel display device may include a light emitting element in which each pixel of a display panel may self-emit light, thereby displaying an image even without the use of a backlight unit to provide light to the display panel.

Recently, display devices tend to include a touch sensing module for sensing a user’s touch as a practical and intuitive input interface. The touch sensing module includes a touch sensing unit in which touch electrodes are arranged, and a touch driving circuit for detecting an amount of charged capacitance between touch electrodes. The touch sensing module may be formed integrally with an image display unit of the display device, or may be mass-produced in a state of being disposed on a front surface of the image display unit.

### SUMMARY

A display device includes a display panel displaying an image. A display driving circuit controls an image display operation of pixels disposed in the display panel. The display panel includes a display module including a thin film transistor layer, a light emitting element layer, and an encapsulation layer, each disposed on a substrate. A noise shielding layer is formed in front of the display module. The display module has a planar mesh shape. A touch sensing unit is disposed in front of the noise shielding layer.

A display device includes a display panel configured to display an image, and a display driving circuit configured to control an image display operation of pixels formed in the display panel. The display panel includes a display module including a thin film transistor layer, a light emitting element layer, and an encapsulation layer, each disposed on a substrate. A noise shielding layer is disposed on a front surface of the display module. The noise shielding layer has a planar mesh shape. A touch sensing unit is disposed on the front surface of the display module, including the noise shielding layer.

An electronic device includes a display device. An image signal processor is configured to control an image display timing of the display device. A power module is configured to provide a power signal to the display device. The display device includes a display panel configured to display an image, and a display driving circuit configured to control an image display operation of pixels formed in the display panel. The display panel includes a display module including a thin film transistor layer, a light emitting element layer, and an encapsulation layer, each disposed on a substrate. A noise shielding layer is formed on a front surface of the display module. The noise shielding layer has a planar mesh shape. A touch sensing unit is disposed in front of the noise shielding layer.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating a display device according to an embodiment;

FIG. 2 is a plan view illustrating a display device according to an embodiment;

FIG. 3 is a side view illustrating a display device according to an embodiment;

FIG. 4 is a schematic layout view illustrating an example of a display panel shown in FIGS. 1 - 3;

FIG. 5 is a detailed plan view illustrating a noise shielding layer of an embodiment, which is arranged on an image display unit of FIG. 3;

FIG. 6 is a detailed plan view illustrating an area A1 of a noise shielding layer shown in FIG. 5;

FIG. 7 is a schematic layout view illustrating a touch sensing unit shown in FIG. 3;

FIG. 8 is a side view illustrating a display device according to an embodiment;

FIG. 9 is a detailed plan view illustrating a noise shielding layer of an embodiment;

FIG. 10 is a detailed plan view illustrating a noise shielding layer of an embodiment;

FIG. 11 is a detailed plan view illustrating a noise shielding layer of an embodiment;

FIG. 12 is a plan view illustrating a first detection method for detecting an area where a difference in the degree of noise shielding occurs;

FIG. 13 is a view illustrating a result of detecting an area where a difference in the degree of noise shielding occurs, through the first detection method of FIG. 12;

FIG. 14 is a plan view illustrating a detection method for detecting an area where a difference in the degree of noise shielding occurs;

FIG. 15 is a view illustrating a result of detecting an area where a difference in the degree of noise shielding occurs, through the detection method of FIG. 14;

FIG. 16 is a block diagram illustrating an electronic device including a display device according to an embodiment of the present disclosure; and

FIG. 17 illustrates schematic diagrams of electronic devices according to various embodiments.

### DETAILED DESCRIPTION OF THE DRAWINGS

The present disclosure will now be described more fully hereinafter with reference to the accompanying drawings, in which embodiments of the disclosure are shown. This disclosure may, however, be embodied in different forms and should not necessarily be construed as limited to the embodiments set forth herein. Rather, these embodiments are provided so that this disclosure will be thorough and complete, and will filly convey the scope of the disclosure to those skilled in the art.

It will also be understood that when a layer is referred to as being "on" another layer or substrate, it can be directly on the other layer or substrate, or intervening layers may also be present. The same reference numbers may indicate the same components throughout the specification and the drawings.

It will be understood that, although the terms “first,” “second,” etc. may be used herein to describe various elements, these elements should not necessarily be limited by these terms. These terms are used to distinguish one element from another element. For instance, a first element discussed below could be termed a second element without departing from the teachings of the present disclosure. Similarly, the second element could also be termed the first element.

Each of the features of the various embodiments of the present disclosure may be combined or combined with each other, in part or in whole, and technically various interlocking and driving are possible. Each embodiment may be implemented independently of each other or may be implemented together in an association.

Embodiments of the present disclosure relate to a display device, particularly suited for integration into electronic products like smartphones, tablets, computer monitors, wearables, and vehicle displays, which combines advanced image rendering with touch input while minimizing electromagnetic interference between the two functions. The display panel may include a substrate supporting a thin film transistor layer, a light emitting element layer, and an encapsulation layer. On the front surface of this module lies a specially designed noise shielding layer with a mesh pattern. This mesh allows light from the pixels to pass without significant luminance loss while blocking electromagnetic noise that could disrupt the touch sensing unit positioned above it. A polarization control layer may be interposed to reduce external light reflection and further protect display quality.

The noise shielding layer is more than a static barrier, it may be engineered for performance monitoring. It may include conductive pattern electrodes arranged in a mesh between pixel emission areas, along with reference signal and sensing lines that connect to pads for electrical testing. By sending reference driving signals through the mesh and measuring return signals, the system’s display driving circuit can detect variations in shielding performance across different display regions. This diagnostic capability allows identification of non-uniformities caused by manufacturing variations, such as differences in layer thickness, line width, or dielectric constant. As a result, the invention not only improves image quality and touch accuracy but also serves as a built-in inspection tool during production or operation.

The touch sensing unit, located in front of the shielding layer (either directly or with the polarization control layer in between), detects user input via capacitance or voltage changes between transparent electrodes. A protective cover window, adhered with an optically clear adhesive or resin, shields the touch and display layers from damage. The architecture supports multiple embodiments with varying configurations of signal lines and detection schemes, but several embodiments share a core principle of using a patterned, optically transparent conductive mesh for noise suppression and diagnostic feedback. This integration yields a robust, high-performance display panel that maintains touch responsiveness and display clarity while enabling precise quality control.

Hereinafter, detailed embodiments will be described with reference to the accompanying drawings.

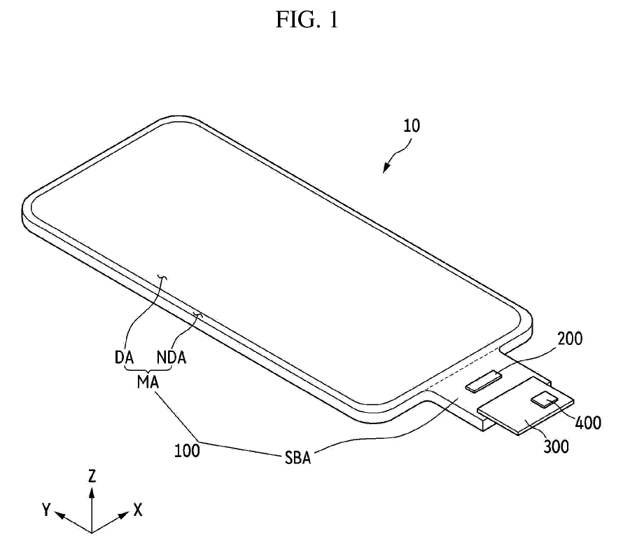

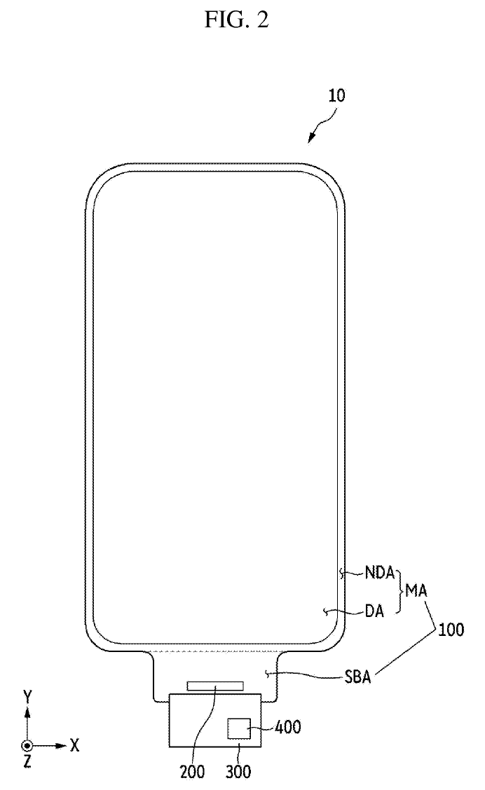

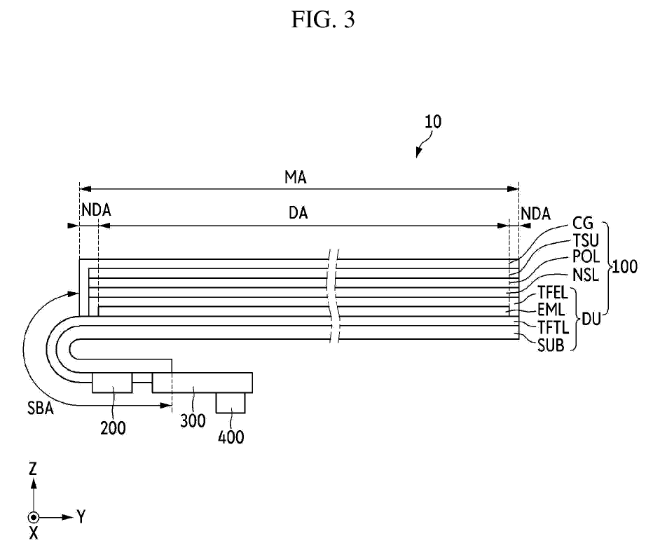

FIG. 1 is a perspective view illustrating a display device according to an embodiment. FIG. 2 is a plan view illustrating a display device according to an embodiment. FIG. 3 is a side view illustrating a display device according to an embodiment.

Referring to FIGS. 1 to 3, a display device 10, according to an embodiment, may be applied to a mobile electronic device such as a mobile phone, a smart phone, a tablet computer, a mobile communication terminal, an electronic diary, an electronic book, a portable multimedia player (PMP), a navigation system, and an ultra mobile PC (UMPC).

Also, the display device 10, according to an embodiment, may be applied to an electronic device, such as a television, a laptop/notebook computer, a computer monitor, a digital signboard/billboard or an Internet of things (IoT) device, as a display unit. Also, the display device 10, according to an embodiment, may be applied to a wearable electronic device, such as a smart watch, a watch phone, an eyeglasses-type display and a head mounted display (HMD), as a display unit. Also, the display device 10, according to an embodiment, may be applied to an electronic device of a vehicle as a display unit. For example, the display device 10, according to an embodiment, may be applied to a dashboard of a vehicle, a center fascia of a vehicle, a center information display (CID) arranged in a dashboard of a vehicle, or a room mirror display that replaces a side mirror of a vehicle, as a display unit.

The display device 10, according to an embodiment, may be a light emitting display device such as an organic light emitting diode (OLED) display device using an organic light emitting diode, a quantum dot light emitting display device including a quantum dot light emitting layer, an inorganic light emitting display device including an inorganic semiconductor, or a micro or nano light emitting display device using a micro or nano light emitting diode (micro LED or nano LED). The following description will be based on the display device 10 being an organic light emitting display device, but the present disclosure is not necessarily limited thereto.

The display device 10, according to an embodiment, may include a display panel 100, a display driving circuit 200, a circuit board 300, and a touch driving module. The touch sensing module includes a touch sensing unit TSU and a touch driving circuit 400.

The display panel 100 may be formed as a rectangular plane having a pair of short sides extending in a first direction (X-axis direction) and a pair of long sides extending in a second direction (Y-axis direction) crossing the first direction (X-axis direction). A corner where a short side extending in the first direction (X-axis direction) and a long side extending in the second direction (Y-axis direction) meet may be rounded to have a curvature or formed at a right angle. A planar shape of the display panel 100 is not necessarily limited to a rectangular shape, and may be formed in another polygonal shape, a circular shape or an oval shape. The display panel 100 may be flat, but is not necessarily limited thereto. For example, the display panel 100 may include a curved portion formed at left and right ends, having a constant curvature or a variable curvature. In addition, the display panel 100 may be flexible, curved, twisted, bent, folded, or rolled.

The display panel 100 includes a main area MA and a sub-area SBA.

The main area MA includes a display area DA for displaying an image and a non-display area NDA that is a peripheral area of the display area DA. The display area DA includes pixels for displaying an image. The sub-area SBA may protrude from one side of the main area MA in the second direction (Y-axis direction).

Although FIGS. 1 and 2 illustrate that the sub-area SBA is unfolded, the sub-area SBA may be bent as shown in FIG. 3, and in this case, the sub-area SBA may be arranged on a lower surface of the display panel 100. When the sub-area SBA is bent, the sub-area SBA may overlap the main area MA in a third direction (Z-axis direction), which is a thickness direction of a substrate SUB. The display driving circuit 200 may be arranged in the sub-area SBA.

As shown in FIG. 3, the display panel 100 includes a display module DU, which includes a substrate SUB, a thin film transistor layer TFTL, a light emitting element layer EML and an encapsulation layer TFEL. The display panel 100 further includes a noise shielding layer NSL of a mesh shape formed on a front surface of the display module DU, a polarization control layer POL formed by covering the front surface of the display module DU, including the noise shielding layer NSL, a passivation layer for protecting the polarization control layer by covering the polarization control layer, and a touch sensing unit TSU formed on a front surface of the passivation layer. Also, the display panel 100 includes a cover window CG formed by covering both the display module DU and the touch sensing unit TSU.

The thin film transistor layer TFTL may be arranged on the substrate SUB. The thin film transistor layer TFTL may be arranged in the main area MA and the sub-area SBA. The thin film transistor layer TFTL includes thin film transistors.

The light emitting element layer EML may be arranged on the thin film transistor layer TFTL. The light emitting element layer EML may be arranged in the display area DA of the main area MA. The light emitting element layer EML includes light emitting elements arranged in light emission areas.

The encapsulation layer TFEL may be arranged on the light emitting element layer EML. The encapsulation layer TFEL may be arranged in the display area DA and the non-display area NDA of the main area MA. The encapsulation layer TFEL includes at least one inorganic layer and at least one organic layer to encapsulate the light emitting element layer.

The noise shielding layer NSL is formed on the front surface of the display module DU including an electrically conductive material such as metal with a mesh shape, to transmit image display light of the display module DU and shield electromagnetic noise generated from the display module DU.

The polarization control layer POL is formed in front of the noise shielding layer NSL. The polarization control layer POL may cover the front surface of the polarization control layer POL including the display module DU to prevent visibility of an image from being deteriorated due to reflection of external light.

The touch sensing unit TSU may be formed integrally with the polarization control layer POL on the front surface of the polarization control layer POL or may be arranged on the front surface of the polarization control layer POL. For example, the touch sensing unit TSU may be formed or arranged in a direction of the front surface of the display area DA to correspond to the display area DA of the main area MA. The touch sensing unit TSU may sense a touch by a human body part such as a finger and an electronic stylus/pen by using the touch electrodes. For example, the touch sensing unit TSU may sense a touch and a touch position by using a voltage magnitude change detection manner or a capacitance detection manner based on the touch electrodes.

The cover window CG for protecting an upper portion of the display panel 100 may be arranged on the touch sensing unit TSU. The cover window CG may be attached onto the touch sensing unit TSU by a transparent adhesive such as an optically clear adhesive (OCA) film or an optically clear resin (OCR). The cover window CG may be an inorganic material such as glass or an organic material such as plastic or a polymer material.

The display driving circuit 200 may generate signals and voltages for driving the display panel 100. The display driving circuit 200 may be formed as an integrated circuit (IC) and attached onto the display panel 100 by a chip on glass (COG) mode, a chip on plastic (COP) mode, or an ultrasonic bonding mode, but is not necessarily limited thereto. For example, the display driving circuit 200 may be attached onto the circuit board 300 by a chip on film (COF) mode.

The display driving circuit 200 detects and identifies noise shielding performance, for example, a difference in a shielding degree or a shielding force for a portion or a partial area of the noise shielding layer NSL formed in a mesh shape. To this end, the display driving circuit 200 supplies a reference driving signal to at least one reference signal line and a reference signal pad, which are electrically connected to the noise shielding layer NSL, and receives a reference sensing signal through at least one signal sensing line and a signal sensing pad, which are electrically connected to the noise shielding layer NSL. In this case, the display driving circuit 200 detects a change in a voltage magnitude or the amount of current of the reference sensing signal.

The display driving circuit 200 performs AD modulation (analog-digital modulation) for the reference sensing signals received through at least one signal sensing line and the signal sensing pad and compares the reference sensing signals with a reference signal such as a reference driving signal, thereby detecting noise shielding performance for a portion or a partial area of the noise shielding layer NSL in accordance with the compared result. For example, the display driving circuit 20 may detect and identify that noise shielding performance is higher as a difference in the voltage magnitude or the amount of current between the reference driving signal or the reference signal and the reference sensing signal is smaller. The comparison result of noise shielding performance may be output as data or may be displayed as an image.

A deviation error in a manufacturing process, such as a line width or a thickness of the noise shielding layer NSL of the mesh shape, may be detected and identified based on the noise shielding performance identified for a portion or partial area of the noise shielding layer NSL. For example, a difference in a thickness of an organic or inorganic layer or a line width or an electrical dielectric constant of lines may be detected for each partial area, in which an image is displayed, depending on the noise shielding performance identified for a portion or partial area of the noise shielding layer NSL. The detected result of the noise shielding performance identified for a portion or partial area of the noise shielding layer NSL may be used as a result of performance inspection or a result of defect inspection of the display panel 100.

The circuit board 300 may be attached to a first end of the sub-area SBA of the display panel 100. For this reason, the circuit board 300 may be electrically connected to the display panel 100 and the display driving circuit 200. The display panel 100 and the display driving circuit 200 may receive digital video data, timing signals, and driving voltages through the circuit board 300. The circuit board 300 may be a flexible printed circuit board, a printed circuit board, or a flexible film such as a chip on film.

The touch driving circuit 400 may be arranged on the circuit board 300. The touch driving circuit 400 may be formed as an integrated circuit (IC) and attached to the circuit board 300. The touch driving circuit 400 is electrically connected to the touch electrodes of the touch sensing unit TSU.

The touch driving circuit 400 applies touch driving signals to the touch electrodes of the touch sensing unit TSU and measures the amount of change in charges of mutual capacitance for a plurality of touch nodes formed by the touch electrodes, thereby recognizing a touch. For example, the touch driving circuit 400 applies touch driving signals to the touch electrodes arranged in the touch sensing unit TSU, and measures a change in capacitance between the touch nodes in accordance with the change in the voltage magnitude or the amount of current of the touch sensing signal received through the touch electrodes. In this way, the touch driving circuit 400 may determine whether there is a user’s touch or a user’s proximity, depending on the amount of change in charges of mutual capacitance of each of the touch nodes.

The user’s touch may refer to a touch by an object such as a user’s finger or a stylus/pen directly contacting one surface of the cover window CG arranged on the touch sensing unit TSU. The user’s proximity may refer to an object such as a user’s finger or a stylus/pen being positioned apart from one surface of the cover window CG (e.g., hovering thereabove without making contact).

The display driving circuit 200 may operate as a main processor or may be formed integrally with the main processor. Accordingly, the display driving circuit 200 may control overall functionality of the display device 10, including the image display operation of the display panel 100. For example, the display driving circuit 200 may receive touch data from the touch driving circuit 400 to determine a user’s touch coordinates and generate digital video data according to the touch coordinates. In addition, the display driving circuit 200 may execute an application indicated by an icon displayed on the user’s touch coordinates. As an example, the display driving circuit 200 may receive coordinate data from an electronic stylus/pen or the like to determine touch coordinates of the electronic stylus/pen, and then may generate digital video data according to the touch coordinates or execute an application indicated by an icon displayed on the touch coordinates of the electronic stylus/pen.

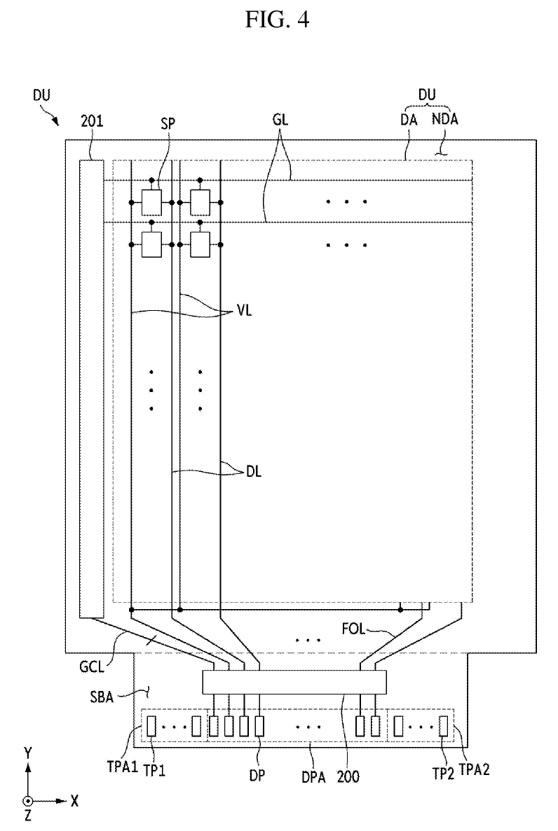

FIG. 4 is a schematic layout view illustrating an example of a display panel shown in FIGS. 1 to 3. For example, FIG. 4 is a layout view illustrating a display area DA and a non-display area NDA of the display module DU in a state before the touch sensing unit TSU is formed.

The display area DA is an area for displaying an image, and may be defined as a central area of the display panel 100. The display area DA may include a plurality of pixels SP, a plurality of gate lines GL, a plurality of data lines DL and a plurality of power lines VL. Each of the pixels SP may be defined as a minimum unit for outputting light.

The plurality of gate lines GL may supply a gate signal received from a gate driver 210 to the plurality of pixels SP. The plurality of gate lines GL may extend in the X-axis direction, and may be spaced apart from each other in the Y-axis direction crossing the X-axis direction.

The plurality of data lines DL may supply a data voltage received from the display driving circuit 200 to the plurality of pixels SP. The plurality of data lines DL may extend in the Y-axis direction, and may be spaced apart from each other in the X-axis direction.

The plurality of power lines VL may supply a power voltage received from the display driving circuit 200 to the plurality of pixels SP. The power voltage may be at least one of a driving voltage, an initialization voltage, or a reference voltage. The plurality of power lines VL may extend in the Y-axis direction, and may be spaced apart from each other in the X-axis direction.

The non-display area NDA may surround the display area DA on at least two opposing sides thereof. The non-display area NDA may include a gate driver 210, fan-out lines FOL, and gate control lines GCL. The gate driver 210 may generate a plurality of gate signals based on a gate control signal and sequentially supply the plurality of gate signals to the plurality of gate lines GL in accordance with a set order.

The fan-out lines FOL may extend from the display driving circuit 200 to the display area DA. The fan-out lines FOL may supply the data voltage received from the display driving circuit 200 to the plurality of data lines DL.

The gate control line GCL may extend from the display driving circuit 200 to the gate driver 210. The gate control line GCL may supply the gate control signal received from the display driving circuit 200 to the gate driver 210.

The sub-area SBA may include a display driving circuit 200, a display pad area DPA, and first and second touch pad areas TPA1 and TPA2.

The display driving circuit 200 may output signals and voltages for driving the display panel 100 to the fan-out lines FOL. The display driving circuit 200 may supply the data voltage to the data line DL through the fan-out lines FOL. The data voltage may be supplied to the plurality of pixels SP, and may determine luminance of the plurality of pixels SP. The display driving circuit 200 may supply the gate control signal to the gate driver 210 through the gate control line GCL.

The display pad area DPA, the first touch pad area TPA1, and the second touch pad area TPA2 may be arranged at an edge of the sub area SBA. The display pad area DPA, the first touch pad area TPA1, and the second touch pad area TPA2 may be electrically connected to the circuit board 300 by using an anisotropic conductive layer or a low resistance and high reliability material such as silver anisotropic paste (SAP).

The display pad area DPA may include a plurality of display pad portions. The plurality of display pad portions may be connected to the display driving circuit 200 or the touch driving circuit 400 through the circuit board 300. The plurality of display pad portions may be connected to the circuit board 300 to receive digital video data, and may supply the digital video data to the display driving circuit 200.

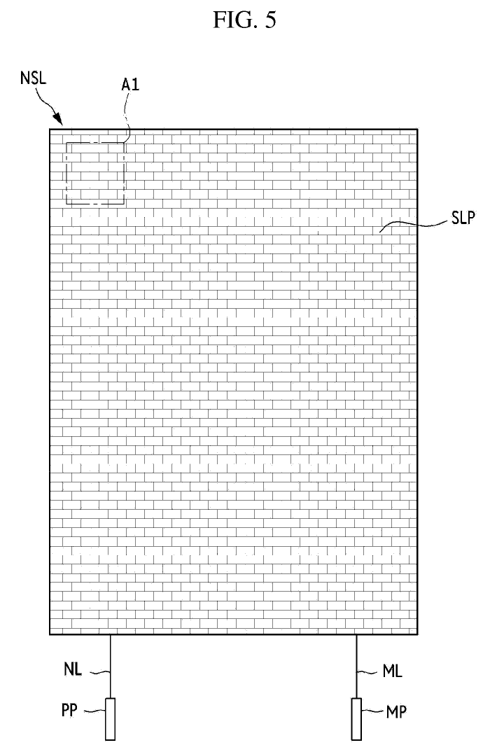

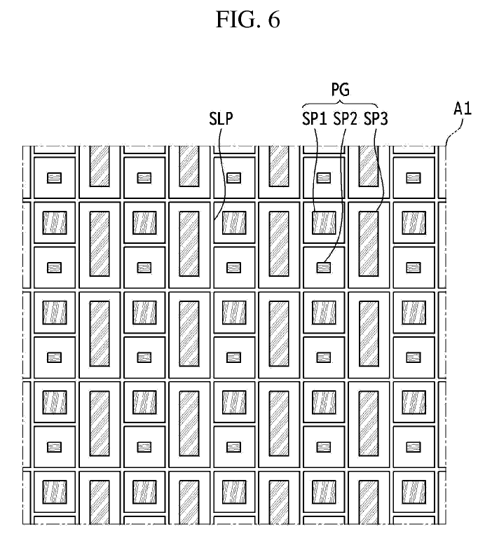

FIG. 5 is a detailed plan view illustrating a noise shielding layer of the first embodiment, which is arranged on an image display unit of FIG. 3. FIG. 6 is a detailed plan view illustrating an area A1 of a noise shielding layer shown in FIG. 5.

Referring to FIGS. 5 and 6, first to third subpixels SP1, SP2 and SP3 may be defined as a unit pixel PG, which is a minimum unit capable of displaying white light, and may be formed and arranged in a matrix shape in the display area DA. Each unit pixel PG may be defined to include a first subpixel SP1 displaying red light, a second subpixel SP2 displaying green light, and a third subpixel SP3 displaying blue light.

Each of the first to third subpixels SP1, SP2 and SP3 may include first to third light emission areas. The first light emission area of the first subpixel SP1 may emit light of a first color or red light, the second light emission area of the second subpixel SP2 may emit light of a second color or green light, and the third light emission area of the third subpixel SP3 may emit light of a third color or blue light. The unit pixels PG and the first to third subpixels SP1, SP2 and SP3 are arranged in a matrix shape. At least one subpixel SP3 of the first to third subpixels SP1, SP2 and SP3 may be formed larger than the other two subpixels SP1 and SP2. Accordingly, each of the unit pixels PG may express a white gray scale through the first to third light emission areas.

The noise shielding layer NSL is arranged and formed in the front direction of the display area DA. The noise shielding layer NSL includes at least one shielding pattern electrode SLP formed in a mesh shape or a net shape along an area between the light emission areas of the first to third subpixels SP1 to SP3 so as not to overlap the light emission areas of each subpixel SP, for example, the first to third subpixels SP1 to SP3.

For example, at least one shielding pattern electrode SLP may be formed in a planar mesh shape or a planar net shape by surrounding an area between and a peripheral area of the first to third light emission areas for each of the first to third subpixels SP1, SP2 and SP3 constituting each unit pixel PG. To this end, at least one shielding pattern electrode SLP includes open areas (e.g., openings), in which electrodes are not formed, in areas corresponding to the first to third light emission areas for each of the first to third subpixels SP1, SP2 and SP3. Each of the open areas formed in at least one shielding pattern electrode SLP may be an area in which at least one shielding pattern electrode SLP is partially opened or cut. Accordingly, since at least one shielding pattern electrode SLP may not overlap the first to third light emission areas, luminance of light emitted from the first to third light emission areas may be prevented from being reduced by at least one shielding pattern electrode SLP.

At least one shielding pattern electrode SLP may include a material, which is transparent and has a high work function, such as indium-tin-oxide (ITO), indium-zinc-oxide (IZO), zinc oxide (ZnO) and indium oxide (In₂O₃). At least one shielding pattern electrode SLP may have a stacked layer structure in which a material layer having the above-described high work function and a reflective material layer such as silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca) or their mixture are stacked. For example, at least one shielding pattern electrode SLP may have a multi-layered structure of ITO/Mg, ITO/MgF, ITO/Ag and ITO/Ag/ITO, but is not necessarily limited thereto.

At least one reference signal line NL is electrically connected to at least one shielding pattern electrode SLP, and at least one reference signal line NL is electrically connected to at least one reference signal pad PP formed in a pad area. For example, at least one reference signal line NL electrically connects at least one shielding pattern electrode SLP to at least one reference signal pad PP.

At least one reference signal line NL may be arranged via the peripheral area of at least one shielding pattern electrode SLP. In addition, at least one reference signal pad PP may be electrically connected to a reference signal supply terminal of the display driving circuit 200.

In addition, at least one signal sensing line ML is electrically connected to at least one shielding pattern electrode SLP, and at least one signal sensing line ML is electrically connected to at least one signal sensing pad MP formed in the pad area. For example, at least one signal sensing line ML electrically connects at least one shielding pattern electrode SLP to at least one signal sensing pad MP.

At least one signal sensing line ML may be arranged via the peripheral area of at least one shielding pattern electrode SLP. In addition, at least one signal sensing pad MP may be electrically connected to a signal sensing terminal of the display driving circuit 200.

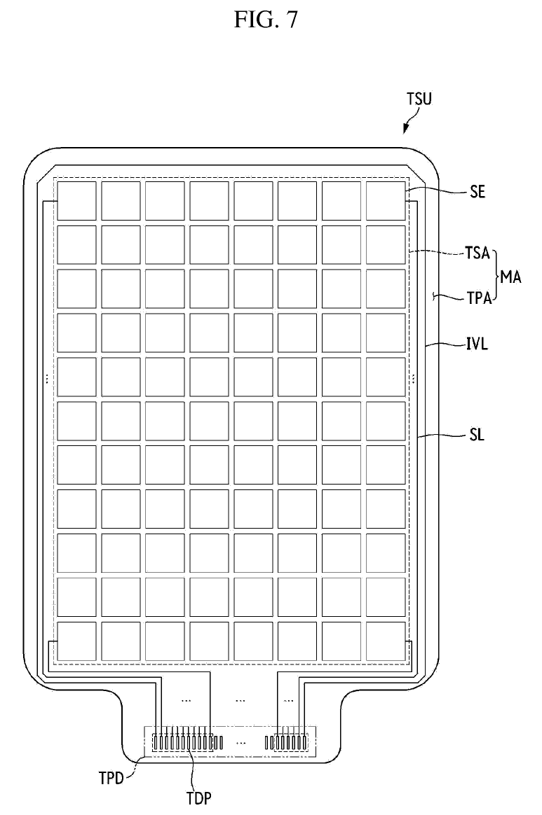

FIG. 7 is a schematic layout view illustrating a touch sensing unit shown in FIG. 3.

Referring to FIG. 7, a plurality of touch electrodes SE may be formed and arranged in a planar matrix shape in a touch sensing area TSA of the touch sensing unit TSU. Each of the touch electrodes SE is connected to each of touch lines SL extending along the touch sensing area TSA and a touch peripheral area TPA on a one-to-one basis.

In FIG. 7, a structure in which each of the touch electrodes SE is formed in a rectangular planar shape is illustrated as an example, but is not necessarily limited thereto. For example, in addition to a rectangle, the touch electrodes SE may be formed in a planar shape such as a rhombus, a square, a polygon other than a rectangle, a circle, or an oval. The touch electrodes SE may include a transparent electrode such as indium tin oxide (ITO), and the touch electrodes SE may include open areas (e.g., openings) in which electrodes are not formed in areas corresponding to the first to third light emission areas of each of the first to third subpixels SP1, SP2 and SP3.

The touch electrodes SE are connected to each of the touch lines SL extending in any one side direction of the touch sensing area TSA to receive a touch driving signal through each of the touch lines SL.

Each of the touch lines SL is connected to touch pads TDP of a touch pad portion TPD formed in the sub-area SBA of the display panel 100 via a portion of the touch peripheral area TPA. For example, each of the touch lines SL may be connected to the touch pads TDP formed in the sub-area SBA via a left or right side and a lower side of the touch sensing area TSA. In this case, each of the touch lines SLs may be connected to the touch pads TDP arranged on the touch pad portion TPD on a one-to-one basis. Additionally, at least one inspection signal transmission line IVL may be arranged in the touch peripheral area TPA along the periphery of the touch sensing area TSA.

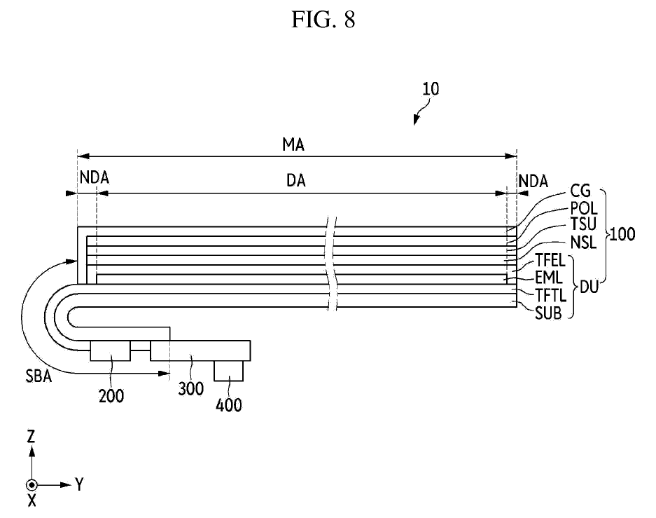

FIG. 8 is a side view illustrating a display device according to the second embodiment.

Referring to FIG. 8, the display panel 100 includes a display module DU including a substrate SUB, a thin film transistor layer TFTL, a light emitting element layer EML and an encapsulation layer TFEL, a noise shielding layer NSL of a mesh type formed on a front surface of the display module DU, and a touch sensing unit TSU arranged on the front surface of the display module DU, including the noise shielding layer NSL. Also, the display panel 100 may further include a polarization control layer POL formed to cover the touch sensing unit TSU, and a cover window CG of the display module DU and touch sensing unit TSU.

The thin film transistor layer TFTL may be arranged on the substrate SUB, and the light emitting element layer EML may be arranged on the thin film transistor layer TFTL. The encapsulation layer TFEL may be arranged on the light emitting element layer EML.

The noise shielding layer NSL is formed on the front surface of the display module DU as a conductive material such as metal with a mesh shape, to transmit image display light of the display module DU and shield electromagnetic noise generated from the display module DU. Also, the noise shielding layer NSL may shield noise in the front direction so that electromagnetic noise generated from the touch sensing unit TSU is not applied in the direction of the display module DU.

The touch sensing unit TSU may be formed on the front surface of the noise shielding layer NSL integrally with the noise shielding layer NSL or may be arranged on the front surface of the noise shielding layer NSL.

The polarization control layer POL may be formed in front of the touch sensing unit TSU. The polarization control layer POL may cover a front surface of the touch sensing unit TSU including the display module DU in order to prevent visibility of an image from being deteriorated due to reflection of external light.

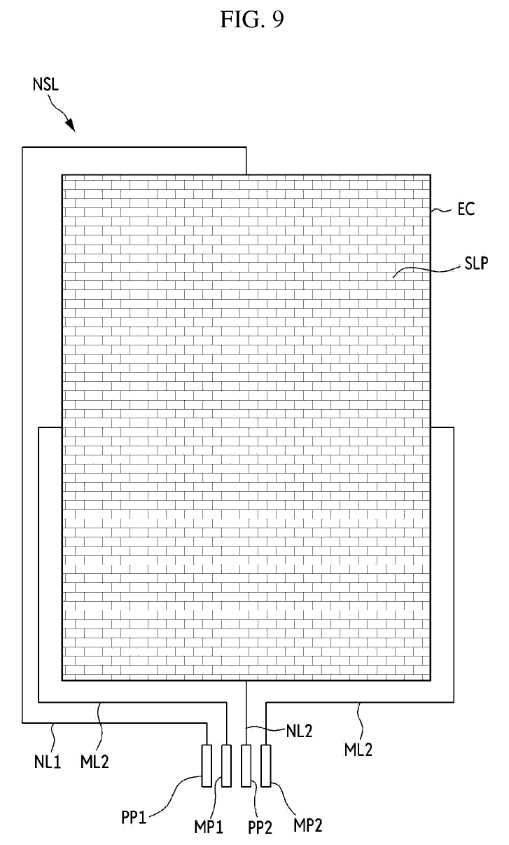

FIG. 9 is a detailed plan view illustrating a noise shielding layer of the second embodiment.

Referring to FIG. 9, the noise shielding layer NSL includes at least one shielding pattern electrode SLP, first and second reference signal lines NL1 and NL2, and first and second signal sensing pads MP1 and MP2.

At least one shielding pattern electrode SLP is formed in a mesh shape or a net shape in an area between the light emission areas of the first to third subpixels SP1 to SP3 so as not to overlap the light emission areas of the subpixels (for example, the first to third subpixels SP1 to SP3) arranged in the display area DA.

A first end of the first reference signal line NL1 is electrically connected to a first direction outer portion of the shielding pattern electrode SLP, and a second end thereof is electrically connected to a first reference signal pad PP1 formed in the pad area, thereby electrically connecting the first direction outer portion of the shielding pattern electrode SLP to the first reference signal pad PP1.

A first end of the second reference signal line NL2 is electrically connected to a second direction outer portion of the shielding pattern electrode SLP, and a second end thereof is electrically connected to a second reference signal pad PP2 formed in the pad area, thereby electrically connecting the second direction outer portion of the shielding pattern electrode SLP to the second reference signal pad PP2.

A first end of the first signal sensing line ML1 is electrically connected to a third direction outer portion of the shielding pattern electrode SLP, and a second end thereof is electrically connected to a first signal sensing pad MP1 formed in the pad area, thereby electrically connecting the third direction outer portion of the shielding pattern electrode SLP to the first signal sensing pad MP1.

A first end of the second signal sensing line ML2 is electrically connected to a fourth direction outer portion of the shielding pattern electrode SLP, and a second end thereof is electrically connected to a second signal sensing pad MP2 formed in the pad area, thereby electrically connecting the fourth direction outer portion of the shielding pattern electrode SLP to the second signal sensing pad MP2.

The display driving circuit 200 detects and identifies noise shielding performance, for example, a difference in a shielding degree or a shielding force for a portion or a partial area of the noise shielding layer NSL formed in a mesh shape. To this end, the display driving circuit 200 supplies the reference driving signal to the first and second reference signal lines NL1 and NL2 through the first and second reference signal pads PP1 and PP2 electrically connected to the shielding pattern electrode SLP, and receives the reference sensing signal through the first and second signal sensing lines ML1 and ML2 and the first and second signal sensing pads MP1 and MP2. In this case, the display driving circuit 200 detects a change in a voltage magnitude or the amount of current of the reference sensing signal.

The display driving circuit 200 performs AD modulation (analog-digital modulation) for the reference sensing signals received through the first and second signal sensing pads and compares the reference sensing signals with the reference signal such as the reference driving signal, thereby detecting noise shielding performance for a portion or partial area of the noise shielding layer NSL in accordance with the compared result. For example, the display driving circuit 20 may determine and identify that noise shielding performance is higher as a difference in the voltage magnitude or the amount of current between the reference driving signal or the reference signal and the reference sensing signal is smaller.

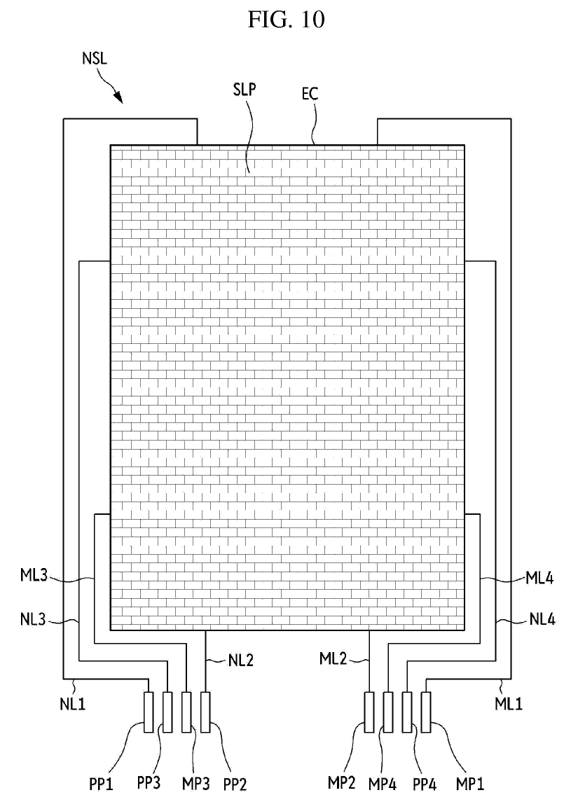

FIG. 10 is a detailed plan view illustrating a noise shielding layer of the third embodiment.

Referring to FIG. 10, the noise shielding layer NSL includes at least one shielding pattern electrode SLP, first to fourth reference signal lines NL1 to NL4, and first to fourth signal sensing pads MP1 to MP4.

At least one shielding pattern electrode SLP is formed in a mesh shape or a net shape in an area between the light emission areas of the first to third subpixels SP1 to SP3 so as not to overlap the light emission areas of the subpixels (for example, the first to third subpixels SP1 to SP3) arranged in the display area DA.

A first end of the first reference signal line NL1 is electrically connected to a first direction outer portion of the shielding pattern electrode SLP, and a second end thereof is electrically connected to a first reference signal pad PP1 formed in the pad area, thereby electrically connecting the first direction outer portion of the shielding pattern electrode SLP to the first reference signal pad PP1.

A first end of the first signal sensing line ML1 is electrically connected to the first direction outer portion of the shielding pattern electrode SLP, and a second end thereof is electrically connected to a first signal sensing pad MP1 formed in the pad area, thereby electrically connecting the first direction outer portion of the shielding pattern electrode SLP to the first signal sensing pad MP1.

A first end of the second reference signal line NL2 is electrically connected to a second direction outer portion of the shielding pattern electrode SLP, and a second end thereof is electrically connected to a second reference signal pad PP2 formed in the pad area, thereby electrically connecting the second direction outer portion of the shielding pattern electrode SLP to the second reference signal pad PP2.

A first end of the second signal sensing line ML2 is electrically connected to the second direction outer portion of the shielding pattern electrode SLP, and a second end thereof is electrically connected to a second signal sensing pad MP2 formed in the pad area, thereby electrically connecting the second direction outer portion of the shielding pattern electrode SLP to the second signal sensing pad MP2.

A first end of the third reference signal line NL3 is electrically connected to a third direction outer portion of the shielding pattern electrode SLP, and a second end thereof is electrically connected to a third reference signal pad PP3 formed in the pad area, thereby electrically connecting the third direction outer portion of the shielding pattern electrode SLP to the third reference signal pad PP3.

A first end of the third signal sensing line ML3 is electrically connected to the third direction outer portion of the shielding pattern electrode SLP, and a second end thereof is electrically connected to a third signal sensing pad MP3 formed in the pad area, thereby electrically connecting the third direction outer portion of the shielding pattern electrode SLP to the third signal sensing pad MP3.

A first end of the fourth reference signal line NL4 is electrically connected to a fourth direction outer portion of the shielding pattern electrode SLP, and a second end thereof is electrically connected to a fourth reference signal pad PP4 formed in the pad area, thereby electrically connecting the fourth direction outer portion of the shielding pattern electrode SLP to the fourth reference signal pad PP4.

A first end of the fourth signal sensing line ML4 is electrically connected to the fourth direction outer portion of the shielding pattern electrode SLP, and a second end thereof is electrically connected to a fourth signal sensing pad MP4 formed in the pad area, thereby electrically connecting the fourth direction outer portion of the shielding pattern electrode SLP to the fourth signal sensing pad MP4.

The display driving circuit 200 detects and identifies noise shielding performance, for example, a difference in a shielding degree or a shielding force for a portion or a partial area of the noise shielding layer NSL formed in a mesh shape. To this end, the display driving circuit 200 supplies the reference driving signal to the first to fourth reference signal lines NL1 to NL4 through the first to fourth reference signal pads PP1 to PP4 electrically connected to the shielding pattern electrode SLP, and receives the reference sensing signal through the first to fourth signal sensing lines ML1 to ML4 and the first to fourth signal sensing pads MP1 to MP4. In this case, the display driving circuit 200 detects a change in a voltage magnitude or the amount of current of the reference sensing signal.

The display driving circuit 200 performs AD modulation (analog-digital modulation) for the reference sensing signals received through the first to fourth signal sensing pads MP1 to MP4 and compares the reference sensing signals with the reference signal such as the reference driving signal, thereby identifying noise shielding performance for a portion or a partial area of the noise shielding layer NSL in accordance with the compared result.

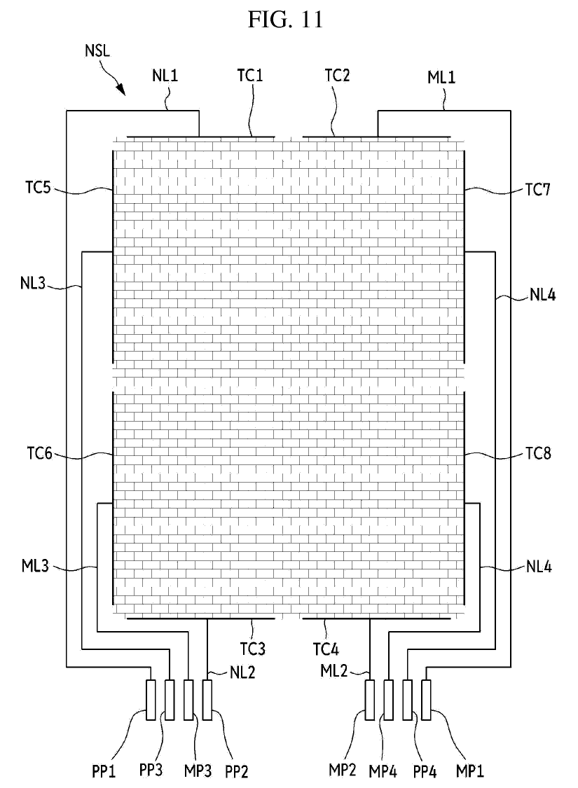

FIG. 11 is a detailed plan view illustrating a noise shielding layer of the fourth embodiment.

Referring to FIG. 11, the noise shielding layer NSL includes at least one shielding pattern electrode SLP, first to fourth reference signal lines NL1 to NL4, and first to fourth signal sensing pads MP1 to MP4.

At least one shielding pattern electrode SLP is formed in a mesh shape or a net shape in an area between the light emission areas of the first to third subpixels SP1 to SP3 so as not to overlap the light emission areas of the subpixels (for example, the first to third subpixels SP1 to SP3) arranged in the display area DA.

A first end of the first reference signal line NL1 is electrically connected to a first connection electrode TC1 of a first direction outer portion of the shielding pattern electrode SLP, and a second end thereof is electrically connected to a first reference signal pad PP1 formed in the pad area, thereby electrically connecting the first connection electrode TC1 of the shielding pattern electrode SLP to the first reference signal pad PP1.

A first end of the first signal sensing line ML1 is electrically connected to a second connection electrode TC2 of the first direction outer portion of the shielding pattern electrode SLP, and a second end thereof is electrically connected to a first signal sensing pad MP1 formed in the pad area, thereby electrically connecting the second connection electrode TC2 of the shielding pattern electrode SLP to the first signal sensing pad MP1.

A first end of the second reference signal line NL2 is electrically connected to a third connection electrode TC3 of a second direction outer portion of the shielding pattern electrode SLP, and a second end thereof is electrically connected to a second reference signal pad PP2 formed in the pad area, thereby electrically connecting the third connection electrode TC3 of the shielding pattern electrode SLP to the second reference signal pad PP2.

A first end of the second signal sensing line ML2 is electrically connected to a fourth connection electrode TC4 of the second direction outer portion of the shielding pattern electrode SLP, and a second end thereof is electrically connected to a second signal sensing pad MP2 formed in the pad area, thereby electrically connecting the fourth connection electrode TC4 of the shielding pattern electrode SLP to the second signal sensing pad MP2.

A first end of the third reference signal line NL3 is electrically connected to a fifth connection electrode TC5 of a third direction outer portion of the shielding pattern electrode SLP, and a second end thereof is electrically connected to a third reference signal pad PP3 formed in the pad area, thereby electrically connecting the fifth connection electrode TC5 of the shielding pattern electrode SLP to the third reference signal pad PP3.

A first end of the third signal sensing line ML3 is electrically connected to a sixth connection electrode TC6 of the third direction outer portion of the shielding pattern electrode SLP, and a second end thereof is electrically connected to a third signal sensing pad MP3 formed in the pad area, thereby electrically connecting the sixth connection electrode TC6 of the shielding pattern electrode SLP to the third signal sensing pad MP3.

A first end of the fourth reference signal line NL4 is electrically connected to a seventh connection electrode TC7 of a fourth direction outer portion of the shielding pattern electrode SLP, and a second end thereof is electrically connected to a fourth reference signal pad PP4 formed in the pad area, thereby electrically connecting the seventh connection electrode TC7 of the shielding pattern electrode SLP to the fourth reference signal pad PP4.

A first end of the fourth signal sensing line ML4 is electrically connected to an eighth connection electrode TC8 of the fourth direction outer portion of the shielding pattern electrode SLP, and a second end thereof is electrically connected to a fourth signal sensing pad MP4 formed in the pad area, thereby electrically connecting the eighth connection electrode TC8 of the shielding pattern electrode SLP to the fourth signal sensing pad MP4.

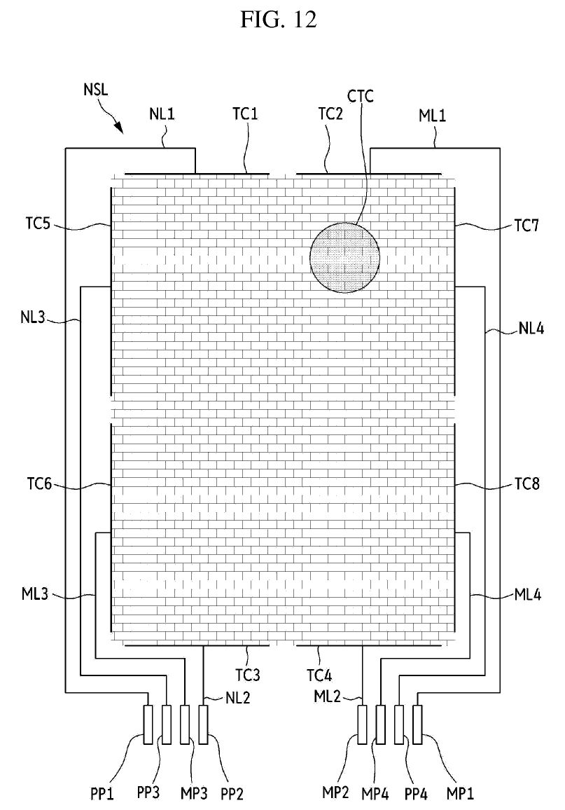

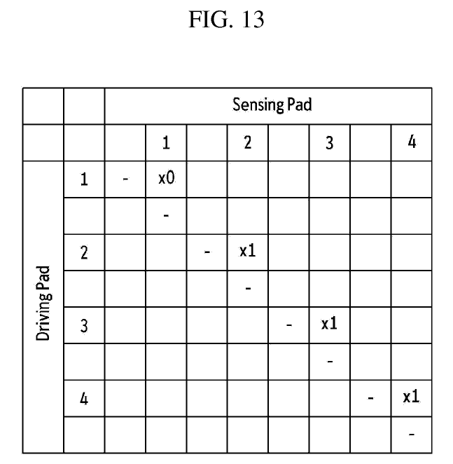

FIG. 12 is a plan view illustrating a first detection method for detecting an area where a difference in the degree of noise shielding occurs. FIG. 13 is a view illustrating a result of detecting an area where a difference in the degree of noise shielding occurs, through the first detection method of FIG. 12.

Referring to FIGS. 12 and 13, the display driving circuit 200 detects and identifies noise shielding performance, for example, a difference in a shielding degree or a shielding force for a portion or a partial area of the noise shielding layer NSL formed in a mesh shape. To this end, the display driving circuit 200 supplies the reference driving signal to the first to fourth reference signal lines NL1 to NL4 through the first to fourth reference signal pads PP1 to PP4 electrically connected to the shielding pattern electrode SLP, and receives the reference sensing signal through the first to fourth signal sensing lines ML1 to ML4 and the first to fourth signal sensing pads MP1 to MP4. In this case, the display driving circuit 200 detects a change in a voltage magnitude or the amount of current of the reference sensing signal.

The display driving circuit 200 performs AD modulation (analog-digital modulation) for the reference sensing signals received through the first to fourth signal sensing pads MP1 to MP4 and compares the reference sensing signals with the reference signal such as the reference driving signal, thereby identifying noise shielding performance for a portion or a partial area of the noise shielding layer NSL in accordance with the compared result.

Referring to FIG. 13, the first to fourth reference signal pads PP1 to PP4 to which the reference driving signal is applied may operate as driving pads. In addition, the first to fourth signal sensing pads MP1 to MP4 may operate as sensing pads.

The display driving circuit 200 may perform AD modulation (analog-digital modulation) for the reference sensing signals received through the first to fourth signal sensing pads MP1 to MP4 and compare the reference sensing signals with a preset reference signal. In this case, when a voltage magnitude or the amount of current, which is sensed through the first to fourth signal sensing pads MP1 to MP4, is lower than or less than a voltage magnitude or the amount of current of the reference signal, it can be noted that noise shielding performance of an area (e.g., CTC area adjacent to the first signal sensing pad MP1) adjacent to the corresponding signal sensing pad has been lowered.

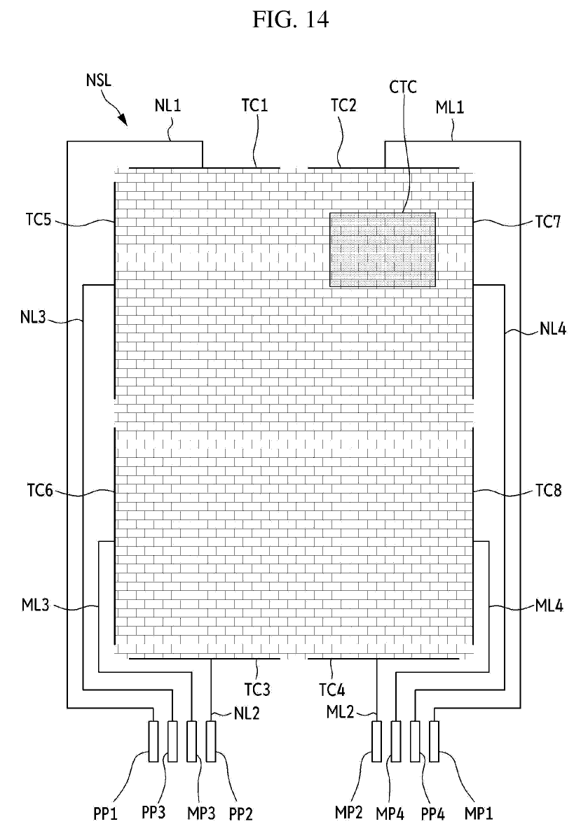

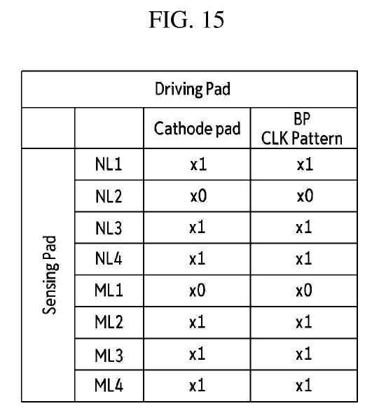

FIG. 14 is a plan view illustrating a second detection method for detecting an area where a difference in the degree of noise shielding occurs. FIG. 15 is a view illustrating a result of detecting an area where a difference in the degree of noise shielding occurs, through the second detection method of FIG. 14.

Referring to FIGS. 14 and 15, the display driving circuit 200 detects and identifies noise shielding performance, for example, a difference in a shielding degree or a shielding force for a portion or a partial area of the noise shielding layer NSL formed in a mesh shape. To this end, the display driving circuit 200 supplies a preset reference driving signal to a cathode pad electrically connected to a common electrode of the thin film transistor layer TFTL or supply the preset reference driving signal to the plurality of gate lines GL or the plurality of data lines DL. For example, the common electrode and the cathode pad of the thin film transistor layer TFTL or clock patterns CLK of the plurality of gate lines GL or the plurality of data lines DL may be used as driving pads. The display driving circuit 200 may receive the reference sensing signal through the first to fourth reference signal pads PP1 to PP4 and the first to fourth signal sensing pads MP1 to MP4, which are electrically connected to the shielding pattern electrode SLP. In this case, the first to fourth reference signal pads PP1 to PP4 and the first to fourth signal sensing pads MP1 to MP4 may be used as sensing pads.

The display driving circuit 200 performs AD modulation (analog-digital modulation) for the reference sensing signals received through the first to fourth reference signal pads PP1 to PP4 and the first to fourth signal sensing pads MP1 to MP4 and compares the reference sensing signals with the reference signal such as the reference driving signal, thereby identifying noise shielding performance for a portion or a partial area of the noise shielding layer NSL in accordance with the compared result. For example, the display driving circuit 200 may perform AD modulation (analog-digital modulation) for the reference sensing signals received through the first to fourth reference signal pads PP1 to PP4 and the first to fourth signal sensing pads MP1 to MP4 and compare the reference sensing signals with a preset reference signal. In this case, when a voltage magnitude or the amount of current, which is sensed through the first to fourth reference signal pads PP1 to PP4 and the first to fourth signal sensing pads MP1 to MP4, is lower than or less than a voltage magnitude or the amount of current of the reference signal, it can be noted that noise shielding performance of an area (e.g., CTC area adjacent to the second signal sensing line ML2) adjacent to the corresponding signal sensing pad has been lowered.

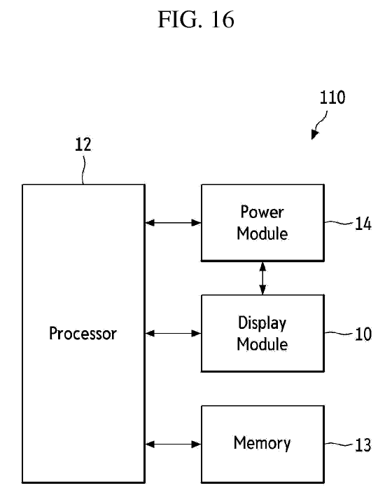

FIG. 16 is a block diagram illustrating an electronic device including a display device according to an embodiment of the present disclosure.

Referring to FIG. 16, an electronic device 110 according to an embodiment may include a display device 10, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

Data information required for an operation of the processor 12 or the display device 10 may be stored in the memory 13. When the processor 12 executes an application stored in the memory 13, an image data signal and/or an input control signal is transmitted to the display device 10, and the display device 10 may process the received signal and output image information through a display screen.

The power module 14 may include a power supply module such as a power adapter or a battery device, and a power conversion module converting a power source supplied by the power supply module to generate a power source required for the operation of the electronic device 110.

At least one of the respective components of the above-described electronic device 110 may be included in the display device according to the above-described embodiments. Also, some of the individual modules functionally included in one module may be included in the display device 10, and others thereof may be provided separately from the display device 10. For example, the display device 10 includes a display panel, and the processor 12, the memory 13 and the power module 14 may be provided as other devices in the electronic device 110 not the display device 10.

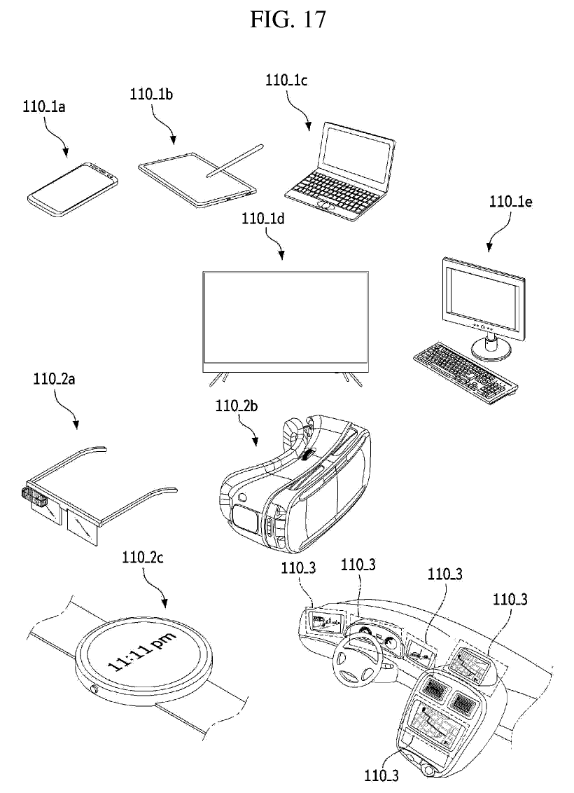

FIG. 17 illustrates schematic diagrams of electronic devices according to various embodiments.

Referring to FIG. 17, various electronic devices 110 to which the display devices 10 according to the embodiments of the present disclosure are applied may include not only electronic devices for image display, such as a smart phone 110_1a, a tablet computer 110_1b, a laptop/notebook computer 110_1c, a TV 110_1d, and a computer monitor 110_1e, but also wearable electronic devices including display modules such as smart glasses 110_2a, a head mounted display 110_2b, and a smart watch 110_2c, and a vehicle electronic device 110_3 including display modules such as a vehicle dashboard, a center fascia, a center information display (CID) arranged on the dashboard, and a room mirror display. In addition, the display device 10 may be applied as a display panel such as that of a television, a laptop/notebook computer, a computer monitor, an advertising board/digital billboard, or an Internet of Things (IOT) device.

In concluding the detailed description, those skilled in the art will appreciate that many variations and modifications can be made to the preferred embodiments without substantially departing from the principles of the present disclosure. Therefore, the disclosed embodiments are used in a generic and descriptive sense and not necessarily for purposes of limitation.

What is claimed is:

1. A display device, comprising
a display panel configured to display an image; and
a display driving circuit configured to control an image display operation of pixels disposed in the display panel,
wherein the display panel includes:
a display module including a thin film transistor layer, a light emitting element layer, and an encapsulation layer, each disposed on a substrate;
a noise shielding layer formed on a front surface of the display module, the noise shielding layer having a planar mesh shape; and
a touch sensing unit disposed in front of the noise shielding layer.

2. The display device of claim 1, further comprising a polarization control layer including the front surface of the display module and the noise shielding layer,
wherein the touch sensing unit is disposed in front of the noise shielding layer with the polarization control layer interposed between the touch sensing unit and the noise shielding layer,
wherein the noise shielding layer includes:
at least one shielding pattern electrode having a mesh or net shape along an area between light emission areas for each pixel so as not to overlap the light emission areas of the pixels;
at least one reference signal line electrically connecting the at least one shielding pattern electrode to at least one reference signal pad; and
at least one signal sensing line electrically connecting the at least one shielding pattern electrode to at least one signal sensing pad.

3. The display device of claim 2, wherein the at least one shielding pattern electrode includes open areas, in which an electrode is not formed, in an area corresponding to the light emission areas of each of the pixels, and
wherein the at least one shielding pattern electrode includes at least one transparent metal electrode of indium-tin-oxide (ITO), indium-zinc-oxide (IZO), zinc oxide (ZnO), or indium oxide (In₂O₃3).

4. The display device of claim 2, wherein the display driving circuit is configured to supply a reference driving signal to the at least one reference signal line and the at least one reference signal pad, and receive a reference sensing signal through the at least one signal sensing line and the at least one signal sensing pad, and
wherein the display driving circuit is configured to detect a change in a voltage magnitude or an amount of current of the reference sensing signal and compare the detected change with a voltage magnitude and the amount of current according to a preset reference signal to detect noise shielding performance for a portion or partial area of the at least one shielding pattern electrode.

5. The display device of claim 2, wherein the noise shielding layer includes:
a first reference signal line in which a first end is electrically connected to a first direction outer portion of the at least one shielding pattern electrode and a second end is electrically connected to a first reference signal pad formed in a pad area;
a second reference signal line in which a first end is electrically connected to a second direction outer portion of the at least one shielding pattern electrode and a second end is electrically connected to a second reference signal pad formed in the pad area;
a first signal sensing line in which a first end is electrically connected to a third direction outer portion of the at least one shielding pattern electrode and a second end is electrically connected to a first signal sensing pad formed in the pad area; and
a second signal sensing line in which a first end is electrically connected to a fourth direction outer portion of the at least one shielding pattern electrode and a second end is electrically connected to a second signal sensing pad formed in the pad area.

6. The display device of claim 5, wherein the display driving circuit is configured to supply a reference driving signal to the first and second reference signal lines through the first and second reference signal pads, and is configured to receive a reference sensing signal through the first and second signal sensing lines and the first and second signal sensing pads, and
wherein the display driving circuit is configured to detect a change in a voltage magnitude or an amount of current of reference sensing signals received through the first and second signal sensing pads and compare the detected change with a voltage magnitude and the amount of current according to a preset reference signal to detect noise shielding performance for a portion or partial area of the at least one shielding pattern electrode.

7. The display device of claim 2, wherein the noise shielding layer includes:
a first reference signal line in which a first end is electrically connected to a first direction outer portion of the at least one shielding pattern electrode and a second end is electrically connected to a first reference signal pad formed in a pad area;
a first signal sensing line in which a first end is electrically connected to the first direction outer portion of the at least one shielding pattern electrode and a second end is electrically connected to a first signal sensing pad formed in the pad area;
a second reference signal line in which a first end is electrically connected to a second direction outer portion of the at least one shielding pattern electrode and a second end is electrically connected to a second reference signal pad formed in the pad area;
a second signal sensing line in which a first end is electrically connected to the second direction outer portion of the at least one shielding pattern electrode and a second end is electrically connected to a second signal sensing pad formed in the pad area;
a third reference signal line in which a first end is electrically connected to a third direction outer portion of the at least one shielding pattern electrode and a second end is electrically connected to a third reference signal pad formed in a pad area;
a third signal sensing line in which a first end is electrically connected to the third direction outer portion of the at least one shielding pattern electrode and a second end is electrically connected to a third signal sensing pad formed in the pad area;
a fourth reference signal line in which a first end is electrically connected to a fourth direction outer portion of the at least one shielding pattern electrode and a second end is electrically connected to a fourth reference signal pad formed in the pad area; and
a fourth signal sensing line in which a first end is electrically connected to the fourth direction outer portion of the at least one shielding pattern electrode and a second end is electrically connected to a fourth signal sensing pad formed in the pad area.

8. The display device of claim 7, wherein the display driving circuit is configured to supply a reference driving signal to the first to fourth reference signal lines through the first to fourth reference signal pads electrically connected to the at least one shielding pattern electrode, and receive a reference sensing signal through the first to fourth signal sensing lines and the first to fourth signal sensing pads, and
wherein the display driving circuit is configured to detect a change in a voltage magnitude or an amount of current of reference sensing signals received through the first to fourth signal sensing pads and compare the detected change with a voltage magnitude and the amount of current according to a preset reference signal to detect noise shielding performance for a portion or partial area of the at least one shielding pattern electrode.

9. The display device of claim 2, wherein the noise shielding layer includes:
a first reference signal line in which a first end is electrically connected to a first connection electrode of a first direction outer portion of the at least one shielding pattern electrode and a second end is electrically connected to a first reference signal pad formed in a pad area;
a first signal sensing line in which a first end is electrically connected to a second connection electrode of the first direction outer portion of the at least one shielding pattern electrode and a second end is electrically connected to a first signal sensing pad formed in the pad area;
a second reference signal line in which a first end is electrically connected to a third connection electrode of a second direction outer portion of the at least one shielding pattern electrode and a second end is electrically connected to a second reference signal pad formed in the pad area;
a second signal sensing line in which a first end is electrically connected to a fourth connection electrode of the second direction outer portion of the at least one shielding pattern electrode and a second end is electrically connected to a second signal sensing pad formed in the pad area;
a third reference signal line in which a first end is electrically connected to a fifth connection electrode of a third direction outer portion of the at least one shielding pattern electrode and a second end is electrically connected to a third reference signal pad formed in a pad area;
a third signal sensing line in which a first end is electrically connected to a sixth connection electrode of the third direction outer portion of the at least one shielding pattern electrode and a second end is electrically connected to a third signal sensing pad formed in the pad area;
a fourth reference signal line in which a first end is electrically connected to a seventh connection electrode of a fourth direction outer portion of the at least one shielding pattern electrode and a second end is electrically connected to a fourth reference signal pad formed in the pad area; and
a fourth signal sensing line in which a first end is electrically connected to an eighth connection electrode of the fourth direction outer portion of the at least one shielding pattern electrode and a second end is electrically connected to a fourth signal sensing pad formed in the pad area.

10. The display device of claim 9, wherein the display driving circuit is configured to supply a reference driving signal to the first to fourth reference signal lines through the first to fourth reference signal pads electrically connected to the at least one shielding pattern electrode, and receive a reference sensing signal through the first to fourth signal sensing lines and the first to fourth signal sensing pads, and
wherein the display driving circuit is configured to detect a change in a voltage magnitude or an amount of current of reference sensing signals received through the first to fourth signal sensing pads and compare the detected change with a voltage magnitude and the amount of current according to a preset reference signal to detect noise shielding performance for a portion or partial area of the at least one shielding pattern electrode.

11. The display device of claim 9, wherein the display driving circuit is configured to supply a reference driving signal to a common electrode formed in a thin film transistor layer of the display panel and a cathode pad electrically connected to the common electrode, or supply the reference driving signal to a plurality gate lines or a plurality of data lines of the display panel,
wherein the display driving circuit is configured to receive reference sensing signals through the first to fourth reference signal pads and the first to fourth signal sensing pads, and
wherein the display driving circuit is configured to detect a change in a voltage magnitude or an amount of current of the reference sensing signals received through the first to fourth reference signal pads and the first to fourth signal sensing pads compares the detected change with a voltage magnitude and the amount of current according to a preset reference signal to detect noise shielding performance for a portion or partial area of the at least one shielding pattern electrode.

12. A display device, comprising
a display panel configured to display an image; and
a display driving circuit configured to control an image display operation of pixels disposed in the display panel,
wherein the display panel includes:
a display module including a thin film transistor layer, a light emitting element layer, and an encapsulation layer, each disposed on a substrate;
a noise shielding layer disposed in front of the display module, the noise shielding layer having a planar mesh shape; and
a touch sensing unit disposed in the front of the display module, the touch sensing unit including the noise shielding layer.

13. The display device of claim 12, further comprising a polarization control layer including the touch sensing unit and a polarizer disposed thereon,
wherein the noise shielding layer includes:
at least one shielding pattern electrode having a mesh or net shape along an area between light emission areas for each pixel so as not to overlap the light emission areas of the pixels;
at least one reference signal line electrically connecting the at least one shielding pattern electrode to at least one reference signal pad; and
at least one signal sensing line electrically connecting the at least one shielding pattern electrode to at least one signal sensing pad.

14. The display device of claim 13, wherein the noise shielding layer includes:
a first reference signal line in which a first end is electrically connected to a first direction outer portion of the at least one shielding pattern electrode and a second end is electrically connected to a first reference signal pad formed in a pad area;
a second reference signal line in which a first end is electrically connected to a second direction outer portion of the at least one shielding pattern electrode and a second end is electrically connected to a second reference signal pad formed in the pad area;
a first signal sensing line in which a first end is electrically connected to a third direction outer portion of the at least one shielding pattern electrode and a second end is electrically connected to a first signal sensing pad formed in the pad area; and
a second signal sensing line in which a first end is electrically connected to a fourth direction outer portion of the at least one shielding pattern electrode and a second end is electrically connected to a second signal sensing pad formed in the pad area.

15. The display device of claim 13, wherein the noise shielding layer includes:
a first reference signal line in which a first end is electrically connected to a first direction outer portion of the at least one shielding pattern electrode and a second end is electrically connected to a first reference signal pad formed in a pad area;
a first signal sensing line in which a first end is electrically connected to the first direction outer portion of the at least one shielding pattern electrode and a second end is electrically connected to a first signal sensing pad formed in the pad area;
a second reference signal line in which a first end is electrically connected to a second direction outer portion of the at least one shielding pattern electrode and a second end is electrically connected to a second reference signal pad formed in the pad area;
a second signal sensing line in which a first end is electrically connected to the second direction outer portion of the at least one shielding pattern electrode and a second end is electrically connected to a second signal sensing pad formed in the pad area;
a third reference signal line in which a first end is electrically connected to a third direction outer portion of the at least one shielding pattern electrode and a second end is electrically connected to a third reference signal pad formed in a pad area;
a third signal sensing line in which a first end is electrically connected to the third direction outer portion of the at least one shielding pattern electrode and a second end is electrically connected to a third signal sensing pad formed in the pad area;
a fourth reference signal line in which a first end is electrically connected to a fourth direction outer portion of the at least one shielding pattern electrode and a second end is electrically connected to a fourth reference signal pad formed in the pad area; and
a fourth signal sensing line in which a first end is electrically connected to the fourth direction outer portion of the at least one shielding pattern electrode and a second end is electrically connected to a fourth signal sensing pad formed in the pad area.

16. The display device of claim 13, wherein the noise shielding layer includes:
a first reference signal line in which a first end is electrically connected to a first connection electrode of a first direction outer portion of the at least one shielding pattern electrode and a second end is electrically connected to a first reference signal pad formed in a pad area;
a first signal sensing line in which a first end is electrically connected to a second connection electrode of the first direction outer portion of the at least one shielding pattern electrode and a second end is electrically connected to a first signal sensing pad formed in the pad area;
a second reference signal line in which a first end is electrically connected to a third connection electrode of a second direction outer portion of the at least one shielding pattern electrode and a second end is electrically connected to a second reference signal pad formed in the pad area;
a second signal sensing line in which a first end is electrically connected to a fourth connection electrode of the second direction outer portion of the at least one shielding pattern electrode and a second end is electrically connected to a second signal sensing pad formed in the pad area;
a third reference signal line in which a first end is electrically connected to a fifth connection electrode of a third direction outer portion of the at least one shielding pattern electrode and a second end is electrically connected to a third reference signal pad formed in a pad area;
a third signal sensing line in which a first end is electrically connected to a sixth connection electrode of the third direction outer portion of the at least one shielding pattern electrode and a second end is electrically connected to a third signal sensing pad formed in the pad area;
a fourth reference signal line in which a first end is electrically connected to a seventh connection electrode of a fourth direction outer portion of the at least one shielding pattern electrode and a second end is electrically connected to a fourth reference signal pad formed in the pad area; and
a fourth signal sensing line in which a first end is electrically connected to an eighth connection electrode of the fourth direction outer portion of the at least one shielding pattern electrode and a second end is electrically connected to a fourth signal sensing pad formed in the pad area.

17. An electronic device, comprising:
a display device;
an image signal processor configured to control an image display timing of the display device; and
a power module configured to provide a power signal to the display device,
wherein the display device includes:
a display panel configured to display an image; and
a display driving circuit configured to control an image display operation of pixels formed in the display panel,
wherein the display panel includes:
a display module including a thin film transistor layer, a light emitting element layer, and an encapsulation layer, each disposed on a substrate;
a noise shielding layer disposed in front of the display module, the noise shielding layer having a planar mesh shape; and
a touch sensing unit disposed in front of the noise shielding layer.

18. The electronic device of claim 17, wherein the display panel is an image display unit of at least one display device of a smart phone, a tablet computer, a laptop/notebook computer, a TV, a computer monitor, smart glasses, a head mounted display, a smart watch, a vehicle dashboard, a center fascia, a center information display (CID), or a room mirror display.

19. The electronic device of claim 17, wherein the display device further includes a polarization control layer including the display module and a polarizer disposed thereon, and
wherein the touch sensing unit is in front of the polarization control layer and covers the polarization control layer.

20. The electronic device of claim 17, wherein the display device further includes a polarization control layer including the display module and a polarizer disposed thereon, the display module including the touch sensing unit; and
a passivation layer covering the polarization control layer.
